(19) United States
(12) Patent Application Publication
(10) Pub. No.: US 2014/0345912 A1
(43) Pub. Date: Nov. 27, 2014

(54) ELECTRIC MULTILAYER PRINTED CIRCUIT BOARD

(71) Applicants: Bernd Eifer, Schorndorf (DE); Jakob Tschritter, Waeschenbeuren (DE)

(72) Inventors: Bernd Eifer, Schorndorf (DE); Jakob Tschritter, Waeschenbeuren (DE)

(73) Assignee: ERNI PRODUCTION GMBH & CO. KG, Adelberg (DE)

(21) Appl. No.: 14/345,436

(22) PCT Filed: Aug. 17, 2012
(86) PCT No.: PCT/DE2012/000830

§ 371 Date: Apr. 11, 2014

(30) Foreign Application Priority Data
Sep. 19, 2011 (DE) 10 2011 113 656.1

(51) Int. Cl. H05K 1/02

(52) U.S. Cl. CPC H05K 1/0216; H05K 1/0298; H05K 2201/0723
USPC 174/251

(57) ABSTRACT

The invention relates to an electric multilayer printed circuit board which satisfies the PICMG specification EXP.O, comprising a first signal layer and a second signal layer. The first signal layer comprises at least one first conductive path (33) and a first shielding region. The second signal layer comprises at least one second conductive path (43) and a second shielding region. The at least one first conductive path (33) and the at least one second conductive path (34) can be arranged such that the paths cross in at least one crossing point K. The first conductive path (33) is arranged adjacently to the second shielding region at each point where the first conductive path does not cross a second conductive path (43), and each second conductive path (43) is arranged adjacently to the first shielding region at each point where the second conductive path does not cross a conductive path (33).

The present invention relates to a multilayer electric printed circuit board which especially satisfies the PICMG specification EXP.0.

### DESCRIPTION OF THE PRIOR ART

It is known to arrange conductive paths carrying high-frequency signals in a signal layer of an electric printed circuit board, which is embedded between shielding layers. The two conductive paths of a symmetric pair of conductors are situated in a plane adjacently to one another. In order to prevent crosstalk between two adjacent pairs of conductors, they can be laid in signal layers stacked on top of one another. This leads to a higher number of signal layers, which increases the thickness of the printed circuit board and increases the production costs.

Electric multilayer printed circuit boards can be configured in such a way so that they can make contact with a plug connector which comprises two three-paired ZD male multipoint connectors. Such printed circuit boards must meet patent-free specifications of PICMG (PCI Industrial Computer Manufacturing Group). Unavoidable crossovers of pairs of conducting paths are obtained by requirements in the PICMG specification EXP.0 CompactPCI Express) for high end systems in 19 inch technology. The conventional technique for unbundling is to provide one respective signal layer per pair of plug connectors. If one layer per pair of plug connectors is still insufficient depending on the respective situation, at least one further signal layer would be required. In the case of the PICMG specification EXP.0, the unbundling to three layers cannot be achieved with conventional technology due to the crossover.

Sufficient signal integrity must be achieved between two signal layers. This requires maintaining the system impedance, which in this case is 100 ohms differentially. Furthermore, a sufficiently low signal crosstalk must be ensured between the conductive paths. This can be achieved by one respective shielding layer (round layer; GND). As a result, the introduction of a further signal layer usually also requires an additional GND layer, which usually leads to the consequence that the production work and therefore the production costs will rise for the multilayer printed circuit board.

It is therefore the object of the present invention to provide a printed circuit board which meets the PICMG specification EXP.0 and requires less input of material during its production than a conventional electric multilayer printed circuit board.

### SUMMARY OF THE INVENTION

The electric multilayer printed circuit board in accordance with the invention comprises a first signal layer and a second signal layer. The first signal layer comprises at least one first conductive path and a first shielding region. The second signal layer comprises at least one second conducting path and a second shielding region. The at least one first conductive path and the at least one second conductive path can be arranged such that said paths cross each other in at least one crossing point. Each first conductive path is arranged adjacently to the second shielding region at each point where the first conductive path does not cross a second conductive path. In particular, it is arranged above the second shielding region. Each second conductive path is arranged adjacently to the first shielding region at each point where the second conductive path does not cross the first conductive path. In particular, it is arranged above the second shielding region.

A conventionally required shielding GND layer between the first signal layer and the second signal layer can be avoided in the multilayer printed circuit board in accordance with the invention because all first conductive paths and second conductive paths are sufficiently remote from each other as a result of the configuration of the printed circuit board in accordance with the invention. The necessary distance between the conductive paths is decreased in accordance with the invention as a result of high coupling of the signals in the conductive paths of each signal layer with an adjacent shielding layer.

A signal layer shall be understood in accordance with the invention as each layer of the multilayer printed circuit board which comprises conductive paths, even if additional shielding regions are situated in said layer. A shielding layer or GND layer shall be understood as each layer which comprises a shielding region and no conductive paths. A shielding region is understood as a region of electrically conductive material which is set up to be grounded in operation of the printed circuit board.

In order to ensure sufficiently low crosstalk between the conductive paths, it is preferable in accordance with the invention that the first signal layer and the second signal layer are arranged between a first shielding layer and a second shielding layer. The distance between the first signal layer and the second signal layer is preferably larger than the distance between the first signal layer and the first shielding layer, and also larger than the distance between the second signal layer and the second shielding layer. This leads to a stronger coupling of the signals with the shielding layers than with the shielding regions of the signal layers.

It is further preferred in accordance with the invention that the electric multilayer printed circuit board comprises a third signal layer which is arranged between the second shielding layer and a third shielding layer, and comprises at least one third conductive path. This ensures the unbundling of all differential signals, which are arranged according to EXP.0 on three rows of pairs of plug connectors, to only three signal layers.

The requirements of the specification EXP.0 can be fulfilled in accordance with the invention in that the third signal layer comprises several third conductive paths and the third conductive paths do not cross each other.

The printed circuit board configuration in accordance with the invention allows that two respective conductive paths (within a pair of conductive paths) are arranged in each signal layer at a distance of a maximum of 300 μm. This allows a highly compact arrangement of the conductive paths.

Furthermore, the use of the first signal layer in accordance with the invention with a first shielding region and a second signal layer with a second shielding region allows the conductive paths to have a structural width of a maximum of 250μ.

The thickness of the signal layers and the thickness of the shielding layers can then be chosen in accordance with the invention as in conventional electric multilayer printed circuit boards, i.e. in a range of 5 μm to 70 μm.

In order to ensure that all signals within a pair of conductive paths cover the distance from one electric contact to another electric contact connected thereto within the same time, it is preferred in accordance with the invention that all conductive paths which are situated in a common pair of conductive paths have the same length. It is especially preferred that all conductive paths which are situated in the same signal layer have the same length. It is especially even more preferable in accordance with the invention that all conductive paths of the electric multilayer printed circuit board have the same length. This can be realised in accordance with the invention in that the conductive paths are not necessarily guided over the shortest possible path between two contacts, but rather have a respectively extended curved progression in order to thus achieve an adjustment of the conductive path length. The term “the same length” shall be understood in accordance with the invention as a length whereby the difference in length between the conductive paths is so small that it is irrelevant for signal integrity.

### BRIEF DESCRIPTION OF THE DRAWINGS

An embodiment of the invention is shown in the drawings and explained in greater detail in the description below, wherein:

FIG. 1 schematically shows a cross-sectional view of an embodiment of the multilayer printed circuit board in accordance with the invention;

FIG. 2 shows the first shielding layer of the multilayer electric printed circuit board according to FIG. 1;

FIG. 3 shows the first signal layer of the multilayer electric printed circuit board according to FIG. 1;

FIG. 4 shows a simplified view of the first signal layer according to FIG. 3;

FIG. 5 shows the second signal layer of the electric multilayer printed circuit board according to FIG. 1;

FIG. 6 shows a simplified illustration of the second signal layer according to FIG. 5;

FIG. 7 shows a simplified view of the conductive paths in the first and the second signal layer of the electric multilayer printed circuit board according to FIG. 1;

FIG. 8 shows the third signal layer of the electric multilayer printed circuit board according to FIG. 1.

### DETAILED DESCRIPTION OF THE PREFERRED EMBODIMENTS OF THE INVENTION

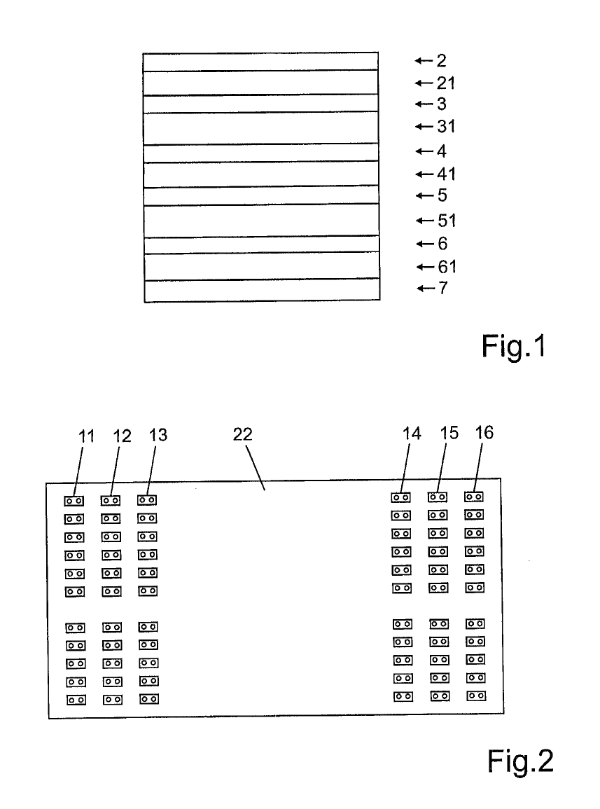

FIG. 1 shows a cross-sectional view through an embodiment of the electric multilayer printed circuit board in accordance with the invention which is not shown true to scale. The uppermost layer of the electric multilayer printed circuit board is a shielding layer 2 which has a thickness of 35 μm. It is applied to a layer 21 which has a thickness of 230 μm and which consists of a semi-finished product of fibres pre-impregnated with a duroplastic synthetic material (first prepreg layer). Said layer 21 is situated on a first signal layer 3 which has a thickness of 35 μm. Said first signal layer 3 is applied to a layer 31 which has a thickness of 1.5 mm and is made of a glass fibre fabric impregnated with epoxy resin (first layer made of base material FR4). The layer 31 is applied to a second signal layer 4 with a thickness of 35 μm. It is applied to a second prepreg layer 41 with a thickness of 230 μm. A second shielding layer 5 with a thickness of 35 μm is situated beneath said layer 41. Said shielding layer 5 is applied to a layer 51 made of base material FR4, which has a thickness of 1.5 mm. The layer 51 is situated on the third signal layer 6 with a thickness of 35 μm. It is applied to a third prepreg layer 61 with a thickness of 230 μm. Said layer 61 is situated above a third shielding layer 7 with a thickness of 35 μm.

The electric multilayer printed circuit board is arranged in such a way that it can be contacted by three-paired ZD male multipoint connectors. It comprises three respective columns of contact pairs at its two ends, which are subdivided into a contact group of 6×3 contact pairs and 5×3 contact pairs. FIG. 2 shows the first shielding layer 2. The illustration shows a first column of contacts 11, a second column of contacts 12 and a third column of contacts 13 at one end of the shielding layer 2. At the opposite end of the shielding layer 2 there is a fourth column of contacts 14, a fifth column of contacts 15 and a sixth column of contacts 16, which are also subdivided into a contact group of 6×3 contact pairs and 5×3 contact pairs of three-paired contacts. A GND shielding region 22 made of copper is situated between the contacts 11, 12, 13, 14, 15, 16. The second shielding layer 5 and the third shielding layer 7 correspond to the first shielding layer 2 with respect to their configuration.

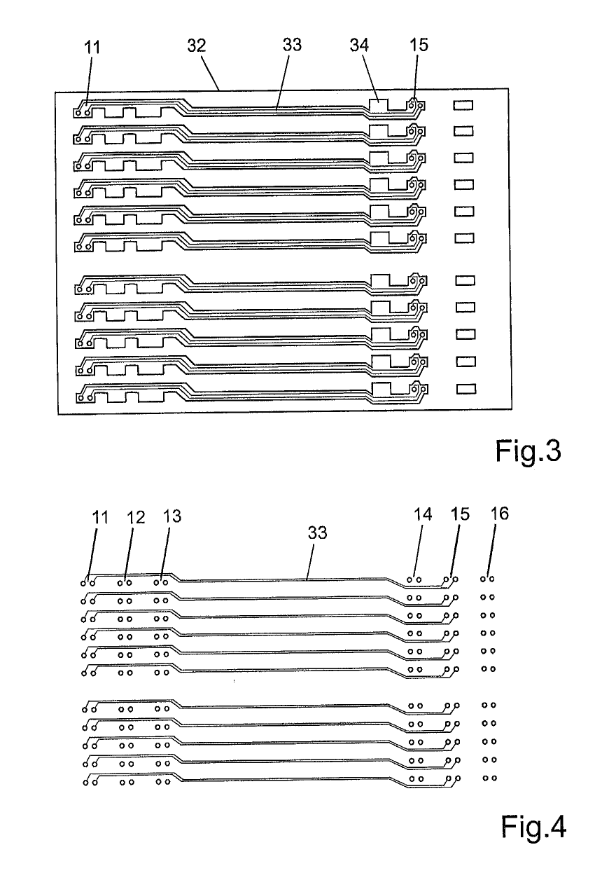

The first signal layer 3 is shown in FIG. 3. The first contact pairs 11 are respectively connected in this illustration to the fifth contact pairs 15. The other contact pairs are not shown in FIG. 3. Each first contact pair 11 is connected by a first pair of conductive paths 33 in an electrically insulating region 34 of the first signal layer 3 to the corresponding fifth contact pair 15 at the other end of the printed circuit board. A distance of 120 μm exists between the two conductive paths of the first pair of conductive paths 33 and each conductive path of each first pair of conductive paths 33 has a structural width of 100 μm. Those regions of the first signal layer 3 which are not covered by the first pairs of conducting paths 33 and the surrounding electrically insulating regions 34 are covered by a first shielding region 32 made of copper. The first pairs of conductive paths 33 are arranged by a curvature in the progression of the conductive paths in such a way that all first conductive paths have the same length. A simplified illustration of the first signal layer 3 is shown in FIG. 4. In this case, all contact pairs 11, 12, 13, 14, 15, 16 and the first pairs of conductive paths 33 are shown here. The curvature of the conductive paths is shown in a simplified view. Moreover, the regions which were covered by the first shielding region 32 are not shown.

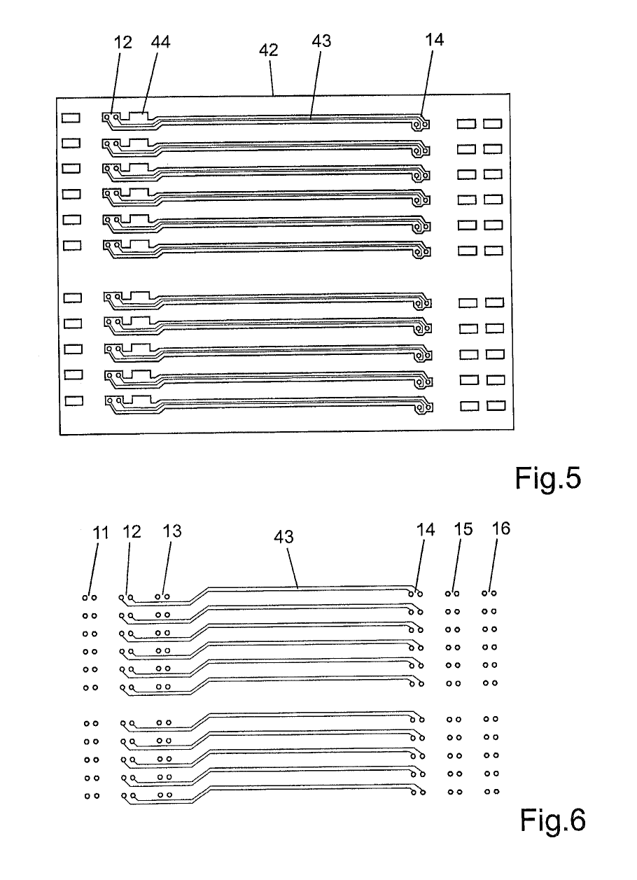

FIG. 5 shows the second signal layer 4 of the electric multilayer printed circuit board. Each second pair of contacts 12 is connected in this case to a fourth pair of contacts 14 by a second pair of conductive paths 43. Electrically insulating regions 44 of the second signal layer 4, which are not covered by a second shielding region 42 made of copper, accommodate the second pairs of conductive paths 43. A distance of 120 μm exists between the two conductive paths of each second pair of conductive paths 43 and each conductive path of each second pair of conductive paths 43 has a structural width of 100 μm. Similar to the conductive paths of the first pair of conductive paths 33, the conductive paths of the second pair of conductive paths 43 are arranged in such a way that all conductive paths of the second pairs of conductive paths 43 have the same length. A simplified illustration of the second signal layer 4 is shown in FIG. 6. It shows all contact pairs 11, 12, 13, 14, 15, 16 and the second pairs of conductive paths 43 by omitting the second shielding region 2.

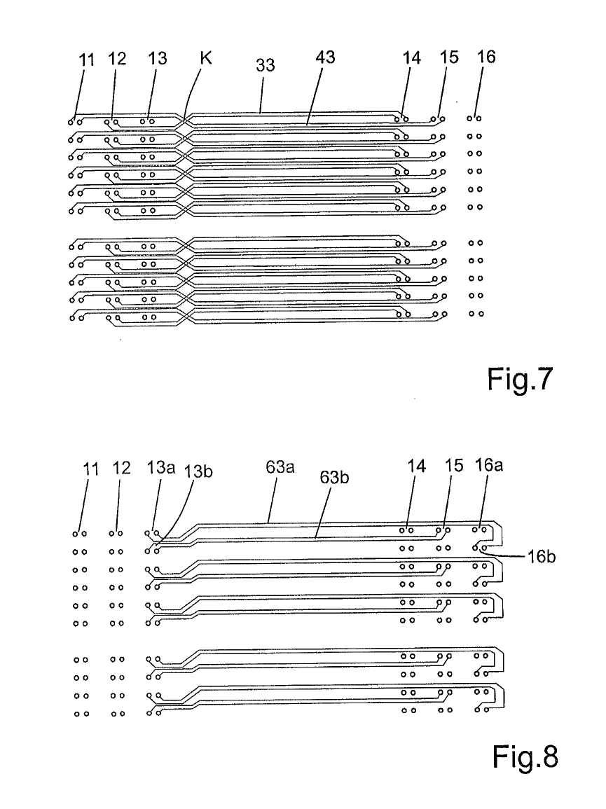

The simplified illustrations of the first signal layer 3 and the second signal layer 4 are placed on top of one another in FIG. 7. The illustration shows that the first pairs of conductive paths 33 of the first signal layer 3 and the second pairs of conductive paths 34 of the second signal layer 4 are arranged to a large part of the signal layers 3, 4 each adjacent to a shielding layer 32, 42 of the respectively other signal layer 3, 4. A crossing of the pairs of conductive paths 33, 43 only occurs in a crossing point K of two respective pairs of conductive paths 33, 43. This is insufficient however in order to cause excessive signal crosstalk between the pairs of conductive paths 33, 43.

FIG. 8 shows the third signal layer 6 of the electric multilayer printed circuit board. It does not comprise a shielding region. A connection between the third contact pairs 13 and the sixth contact pairs 16 occurs in this signal layer. In this case, the third contact pair 13a of a first row of contact pairs is connected to the sixth contact pair 16a of a second contact row via a third pair of conductive paths 36, and a third contact pair 13b of a second contact row is connected to a sixth contact pair 16a of a first signal row via another third pair of conductive paths 63b. This allows a connection of the contact pairs 13a, 13b, 16a, 16b without crossing the third pairs of conductive paths 63a, 63b. A distance of 120 μm is provided between the two conductive paths of each third pair of conductive paths 63a, 63b, and each conductive path of each third pair of conductive paths 63a, 63b has a structural width of 100 μm. Similar to the conductive paths of the first pairs of conductive paths 33 and the second pairs of conductive paths 43, the conductive paths of the third pairs of conductive paths 63a, 63b are curved in such a way that all conductive paths have the same length.

Since the electric multilayer printed circuit board in accordance with the invention does not require any shielding layer between the first signal layer 3 and the second signal layer 4, it can be produced with lower material input than a conventional multilayer printed circuit board which satisfies the PICMG specification EXP.0.

List of reference numerals

```
11: First contact pair
12: Second contact pair
13: Third contact pair
13a: Third contact pair (row 1)
13b: Third contact pair (row 2)
14: Fourth contact pair
15: Fifth contact pair
16: Sixth contact pair
16a: Sixth contact pair (row 1)
16b: Sixth contact pair (row 2)
  2: First shielding layer
21: First prepreg layer
22: GND shielding region
  3: First signal layer
31: First FR4 layer
32: First shielding region
33: First pair of conductive paths
34: First insulating region
  4: Second signal layer
41: Second prepreg layer
42: Second shielding region
43: Second pair of conductive paths
44: Second insulating region
  5: Second shielding layer
  6: Third signal layer
61: Third prepreg layer
63a: Third pair of conductive paths
63b: Third pair of conductive paths
  7: Third shielding layer
K: Crossing point
```

1. An electric multilayer printed circuit board, comprising a first signal layer (3) and a second signal layer (4), wherein
the first signal layer (3) comprises at least one first conductive path (33) and one first shielding region (32), and
the second signal layer (4) comprises at least one second conductive path (43) and one second shielding region (42), wherein the at least one first conductive path (33) and the at least one second conductive path (43) can be arranged in such a way that they cross each other in at least one crossing point (K), and wherein each first conductive path (33) is arranged adjacent to the second shielding region (42) in each point where it does not cross with a second conductive path (43), and each second conductive path (43) is arranged adjacent to the first shielding region 43) in each point where it does not cross with a first conductive path (33).

2. An electric multilayer printed circuit board according to claim 1, wherein each first conductive path (33) is arranged above the second shielding region (42) in each point where it does not cross with a second conductive path (43), and each second conductive path (43) is arranged above the first shielding region (32) in each point where it does not cross with a first conductive path (33).

3. An electric multilayer printed circuit board according to claim 1, wherein the first signal layer (3) and the second signal layer (4) are arranged between a first shielding layer (2) and a second shielding layer (5).

4. An electric multilayer printed circuit board according to claim 3, wherein the distance between the first signal layer and the second signal layer is greater than the distance between the first signal layer and the first shielding layer, and the distance between the first signal layer and the second signal layer is greater than the distance between the second signal layer and the second shielding layer.

5. An electric multilayer printed circuit board according to claim 3, wherein it comprises a third signal layer (6) which is arranged between the second shielding layer (5) and a third shielding layer (7), and comprises at least one third conductive path (63a, 63b).

6. An electric multilayer printed circuit board according to claim 5, wherein it comprises several third conductive paths (63a, 63b) and the third conductive paths (63a, 63b) do not cross each other.

7. An electric multilayer printed circuit board according to claim 1, wherein two respective conductive paths of a pair of conductive paths (33, 43, 63a, 63b) are arranged in each signal layer (3, 4, 6) at a distance of a maximum of 300 μm.

8. An electric multilayer printed circuit board according to claim 1, wherein the conductive paths (33, 43, 63a, 63b) have a structural width of a maximum of 250 μm.

9. An electric multilayer printed circuit board according to claim 1, wherein the thickness of the signal layers (3, 4, 6) and the shielding layers (2, 5, 7) respectively lie in the range of 5 μm to 70 μm.

10. An electric multilayer printed circuit board according to claim 1, wherein all conductive paths which are situated in a common pair of conductive paths (33, 43, 63a, 63b) have the same length.

11. An electric multilayer printed circuit board according to claim 10, wherein all conductive paths (33, 43, 63a, 63b) which are situated in the same signal layer (3, 6) have the same length.

12. An electric multilayer printed circuit board according to claim 11, wherein all conductive paths (33, 43, 63a, 63b) of the electric multilayer printed circuit board have the same length.
